(19) United States
(12) Patent Application Publication
(10) Pub. No.: US 2015/0104277 A1
(43) Pub. Date: Apr. 16, 2015

(54) PRODUCT CARTRIDGE FOR TRANSPORTING PRODUCT

(71) Applicant: GT CRYSTAL SYSTEMS, LLC

(72) Inventors: David J. Dubiel, Goffstown, NH (US); Glenn T. Douglas, Londonderry, NH (US); Steven Garrant, Mont Vernon, NH (US)

(21) Appl. No.: 14/489,674

(22) Filed: Sep. 18, 2014

Related U.S. Application Data
(60) Provisional application No. 61/891,701, filed on Oct. 16, 2013.

(51) Int. Cl. H01L 21/677; H01L 21/68

(52) U.S. Cl. CPC H01L 21/67769; H01L 21/67766; H01L 21/67781; H01L 21/67775; H01L 21/68
USPC 414/267; 414/807; 414/808

(57) ABSTRACT

According to the disclosed embodiments, an illustrative product cartridge comprises first and second opposing walls separated by a distance defined by a product to be transported by the cartridge, the first and second walls configured to define a product access aperture to allow ingress and egress of a plurality of instances of the product between the first and second walls. The product cartridge also comprises product engaging members disposed on the first and second walls, the product engaging members configured to slidingly engage and secure the plurality of instances of the product in parallel when inserted into the product access aperture and at a defined spacing between the plurality of instances of the product. A transfer access aperture opposite the product access aperture is configured to allow an external object to substantially simultaneously push each of the plurality of instances of the product out of the product access aperture.

### CROSS-REFERENCE TO RELATED APPLICATION

The present application claims the benefit of U.S. Patent Application No. 61/891,701 filed Oct. 16, 2013, which is incorporated herein by reference.

### TECHNICAL FIELD

The present disclosure relates generally to product transport, and, more particularly, to a product cartridge for transporting product.

### BACKGROUND

Manufacturing processes are typically concerned with the management of materials and products, particularly with regard to their transport and storage. As a specific example, transferring rectangular/square products from process to process can cause many issues in manufacturing. For instance, such rectangular/square products may be sheets, wafers, boards (e.g., circuit boards), and may be made of any number of materials, such as glass, plastic, or even crystalline structures, such as sapphire. Often, these materials/products are fragile, and require special handling, which can be a difficult problem to overcome, particularly where high-volume demands are present. Furthermore, in some applications, the handling of materials after processing is to be avoided to prevent product contamination.

### SUMMARY

According to the disclosed embodiments, an illustrative product cartridge comprises first and second opposing walls separated by a distance defined by a product to be transported by the cartridge, the first and second walls configured to define a product access aperture to allow ingress and egress of a plurality of instances of the product between the first and second walls. The product cartridge also comprises product engaging members disposed on the first and second walls, the product engaging members configured to slidingly engage and secure the plurality of instances of the product in parallel when inserted into the product access aperture and at a defined spacing between the plurality of instances of the product. A transfer access aperture opposite the product access aperture is configured to allow an external object to substantially simultaneously push each of the plurality of instances of the product out of the product access aperture.

### BRIEF DESCRIPTION OF THE DRAWINGS

The foregoing and other objects, features, aspects and advantages of the embodiments disclosed herein will become more apparent from the following detailed description when taken in conjunction with the following accompanying drawings.

FIG. 1 illustrates an example product cartridge;

FIG. 2 illustrates an example transfer access slot on the product cartridge;

FIG. 3 illustrates an example product spacing within the product cartridge;

FIG. 4 illustrates an example product cartridge loaded within a transfer fixture;

FIG. 5 illustrates an example product cartridge loaded within a stackable rack transfer fixture;

FIG. 6 illustrates an example of product being pushed from the product cartridge into the stackable rack;

FIG. 7 illustrates an example of a pusher retracted from the product cartridge;

FIG. 8 illustrates an example movement of the stackable rack;

FIG. 9 illustrates an example product cartridge loaded to a transfer fixture and associated carrier (end effector);

FIG. 10 illustrates an example of product being pushed from the product cartridge into the transfer fixture;

FIG. 11 illustrates an example of product being moved by the carrier within the transfer fixture;

FIG. 12 illustrates an example of product being moved to a fixed rack;

FIG. 13 illustrates an example of product being placed within the fixed rack;

FIG. 14 illustrates an example of product resting within the fixed rack once the carrier is removed;

FIG. 15 illustrates an example simplified procedure for use with product cartridge described herein; and

FIG. 16 illustrates an example simplified procedure for use with the transfer fixtures described herein.

It should be understood that the above-referenced drawings are not necessarily to scale, presenting a somewhat simplified representation of various preferred features illustrative of the basic principles of the disclosure. The specific design features of the present disclosure, including, for example, specific dimensions, orientations, locations, and shapes, will be determined in part by the particular intended application and use environment.

### DETAILED DESCRIPTION OF THE EMBODIMENTS

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The embodiments herein generally describe high-density product transfer mechanisms and processes, where the product carrier or “cartridge” is integral in the packaging of the products (e.g., sapphire wafers, semiconductor wafers, etc.). The techniques herein not only protect the product, but guarantee the correct spacing for transferring the product to other devices. As described in greater detail below, such a product cartridge transfers product (e.g., rectangular/square product) from a cartridge to work racks, such as those used in an annealing furnace of a sapphire sheet or wafer manufacturing process. (Notably, any references to sapphire or wafers is merely an example, and is not meant to limit the scope of the embodiments herein.) The cartridge itself is illustratively designed to limit any contact of the products, and is sturdy enough for shipping products, such as from a rough-sized stage to final delivery. In this manner, high-density transfer (e.g., a 100 piece transfer device) can be accomplished with minimal product contact, while avoiding use (contact) with primary “viewing” surfaces (e.g., the planar surfaces of a sapphire sheet or wafer) during the transfer and handling of the product. Also, as described herein, the illustrative design has registration to a transfer fixture that allows accurate transfer of product into and out of the cartridge, such as to integrated work rack designs (e.g., using a tooling fixture to transfer the product into the work racks). Note that as detailed below, there are two illustrative rack transfer embodiments described herein, i.e., fixed rack transfer and stackable rack transfer.

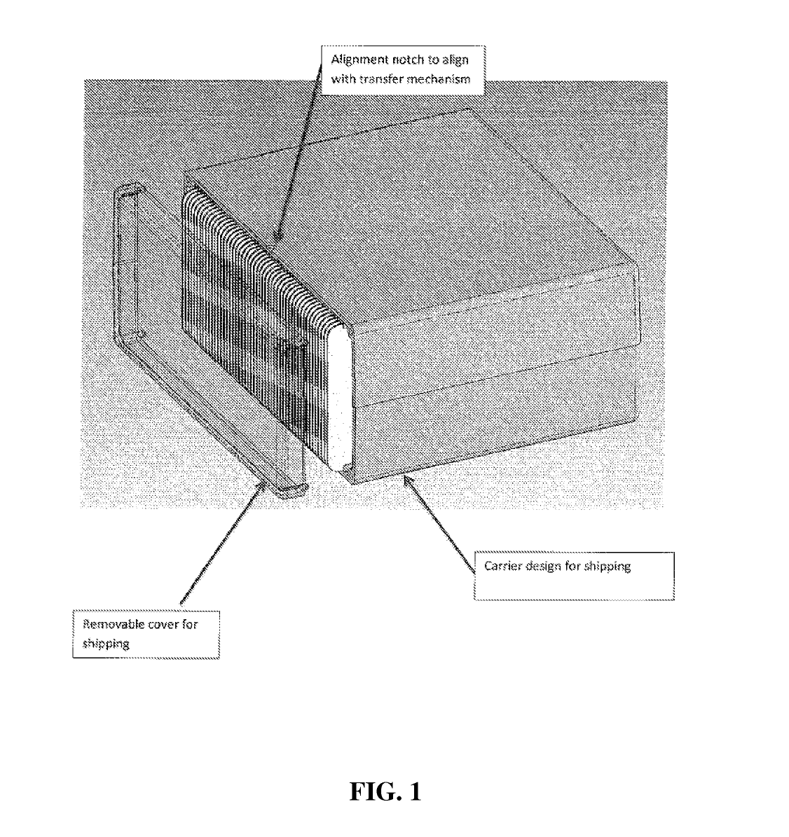

FIG. 1 illustrates an example product cartridge in accordance with one or more illustrative embodiments herein. In particular, first and second opposing walls (e.g., top and bottom) of the cartridge (carrier) are separated by a distance that may generally be defined by the particular product to be transported (e.g., substantially square or rectangular sapphire wafers). Note that while the shape of the cartridge is shown as a generally rectangular shape, particularly where the first and second opposing walls are substantially parallel and planar, other suitable shapes and orientations may be used herein. In addition, while the first and second opposing walls reference the top and bottom walls (e.g., in a horizontal position), the techniques and structures herein may equally apply to alternative orientations (e.g., vertical).

The first and second walls are configured to define a product access aperture (opening) to allow ingress and egress of the product between the first and second walls. In other words, the product (shown as a plurality of parallel instances of the product) may be inserted and removed from one “end” of the cartridge. Also, a removable cover may be configured to prevent egress of inserted product from the product access aperture (i.e., covering, at least partially, the product access aperture). The cover may be used particularly during shipping, and may also prevent contamination of the product or cartridge when not in use. Note also that an alignment mechanism (e.g., notch) may be used to provide aligned engagement of the apparatus with a transfer mechanism, that is, a receiving member for one or both of ingress and egress of the product from the product access aperture.

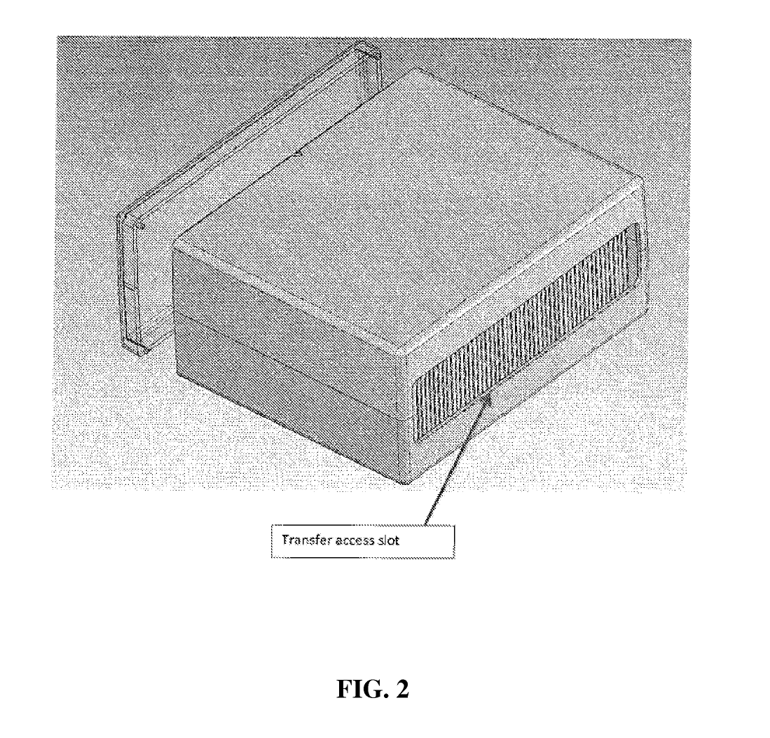

FIG. 2 illustrates an example transfer access slot (aperture) on the product cartridge, generally opposite the product access aperture. In one embodiment, the transfer access aperture is sufficiently smaller than the distance between the first and second walls to prevent egress of the product through the transfer access aperture (i.e., preventing the product from exiting the back of the cartridge), while at the same time being configured to allow an external object (e.g., “pusher” or “push rod” etc.) to push the product from the cartridge, as described in greater detail below. For instance, as shown below, the transfer access aperture allows such an external object/pusher to substantially simultaneously push the product, or more particularly, each of the plurality of instances of the product, out of the product access aperture on the other side (e.g., completely removing the product from the cartridge, or at least partially pushing it out for acquisition by another device or manual operator). Note that while the transfer access aperture is shown spanning the “width” of all of the plurality of product instances, in an alternative embodiment it may be smaller than the span of the plurality of instances of the product, and an internal push plate may be contained within the cartridge that is configured to allow an external object to enter the transfer access aperture and push the push plate to substantially simultaneously push each of the plurality of instances of the product out of the product access aperture.

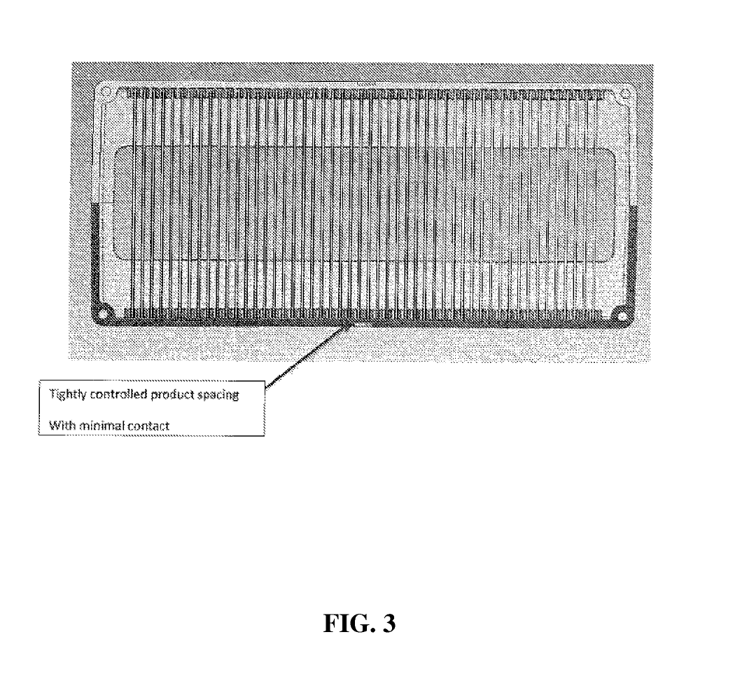

FIG. 3 illustrates an example product spacing within the product cartridge, generally from the perspective of looking into the cartridge through the product access aperture. As shown, product engaging members (“spacers”) are disposed on the first and second walls, where the product engaging members are configured to slidingly engage (i.e., allow for sliding the product into the cartridge) and secure the plurality of instances of the product in parallel when inserted into the product access aperture. In a preferred embodiment, the spacers provide defined spacing between the plurality of instances of the product, such as a minimum distance defined by maximum deflection of two adjacent instances of the product to prevent contact between the two adjacent instances, particularly during transport. In general, the spacers may be individually spaced members along the first and second walls or else may be singular members along the first and second walls defining channels into which instances of the product may slidingly engage. Examples of slidingly engaging members may comprise rollers or a slidingly engaging solid material, such as foam, felt, plastic, various fire proof materials or heat resistant materials, etc.

In general, mechanisms may be in place to manage the cartridge, such as transporting the cartridge, as well as to manage the product (e.g., the plurality of instances of the product), such as insertion means (e.g., automatic or manual) to insert the plurality of instances of the product into the product access aperture or removal means (e.g., automatic or manual) to push an external object through the transfer access aperture to substantially simultaneously push each of the plurality of instances of the product out of the product access aperture.

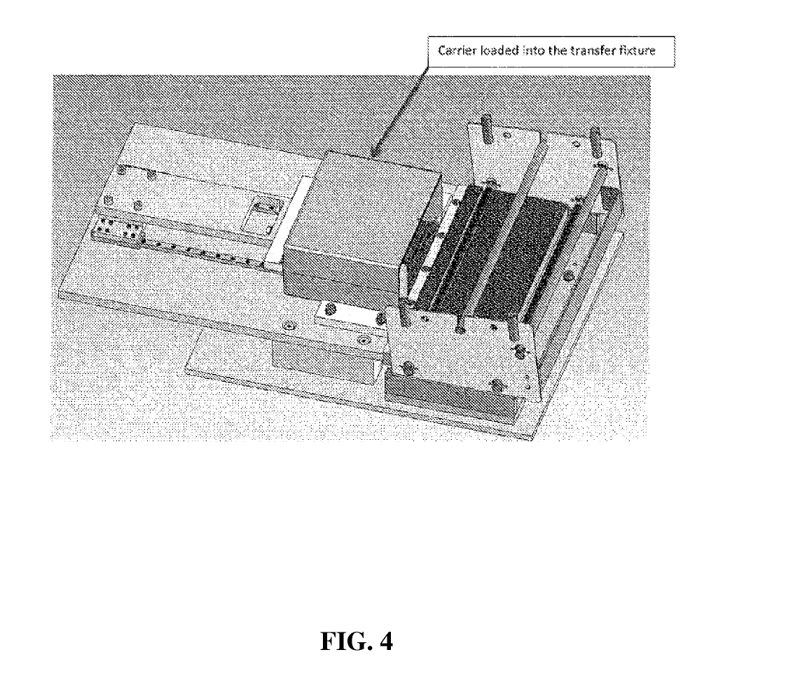

FIG. 4 illustrates an example product cartridge loaded within a transfer fixture, where a cartridge-receiving member (configured to receive a product cartridge/carrier) and a product-receiving member (configured to receive product from the product cartridge) operate in conjunction to remove the product from the cartridge. In particular, the product-receiving member may generally have a bottom support to gravitationally support the product and a rear support to terminate receipt of the product and prevent egress of the product from the product-receiving member, while the system as a whole also has a pusher assembly configured to pushingly engage the product out of the cartridge onto the product-receiving member. More detailed examples and alternative embodiments are described below.

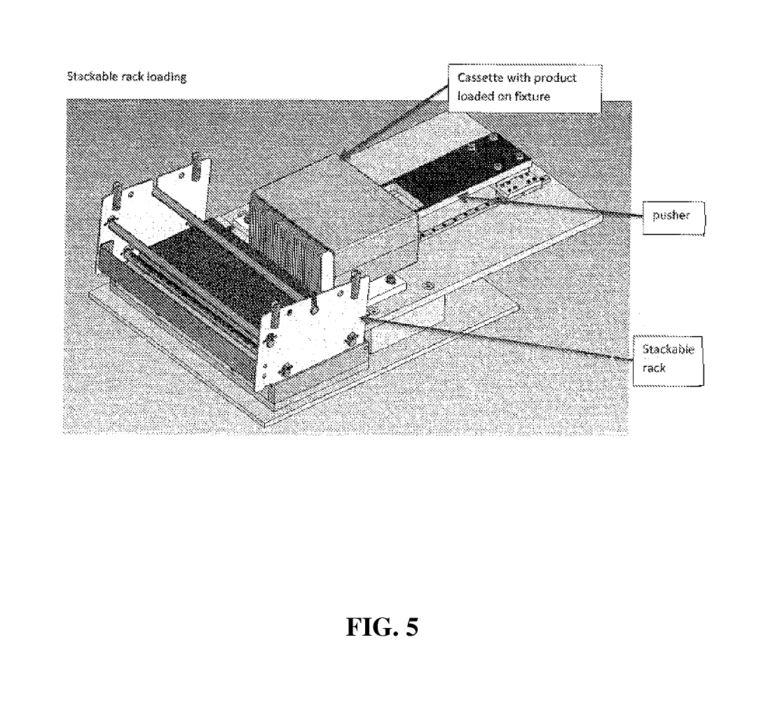

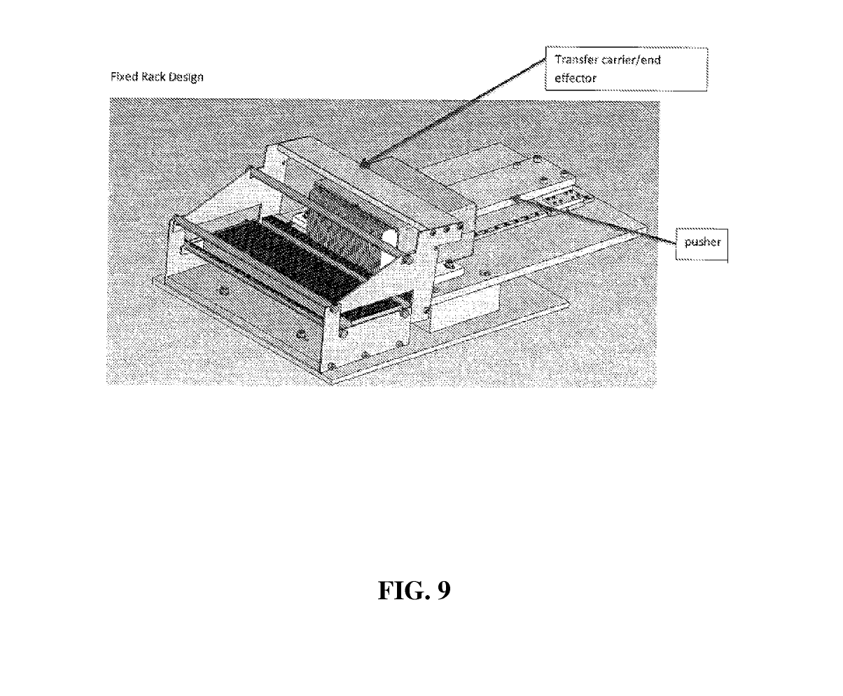

In particular, FIG. 5 illustrates an example product cartridge loaded within a stackable rack transfer fixture, though certain key elements are applicable to stackable racks or a support-only model as described below (e.g., with reference to FIG. 9). In generally, the cartridge (cassette) may be loaded onto the fixture, and aligned with a stackable rack. Within the stackable rack are the rear support (e.g., a rod) and bottom support (e.g., illustratively two spaced rods). Note that in one embodiment, the bottom support may slope downward away from the cartridge-receiving member toward the rear support. In addition, as a preferable option, the system may also have a top support (e.g., rod) configured to compressively support the product against the bottom support, such as through gravity-based weighted compression. In this manner, where the product comprises a plurality of individual separated and parallel instances of the product, the top support compressively supports the plurality of individual separated and parallel instances of the product to maintain separation between them.

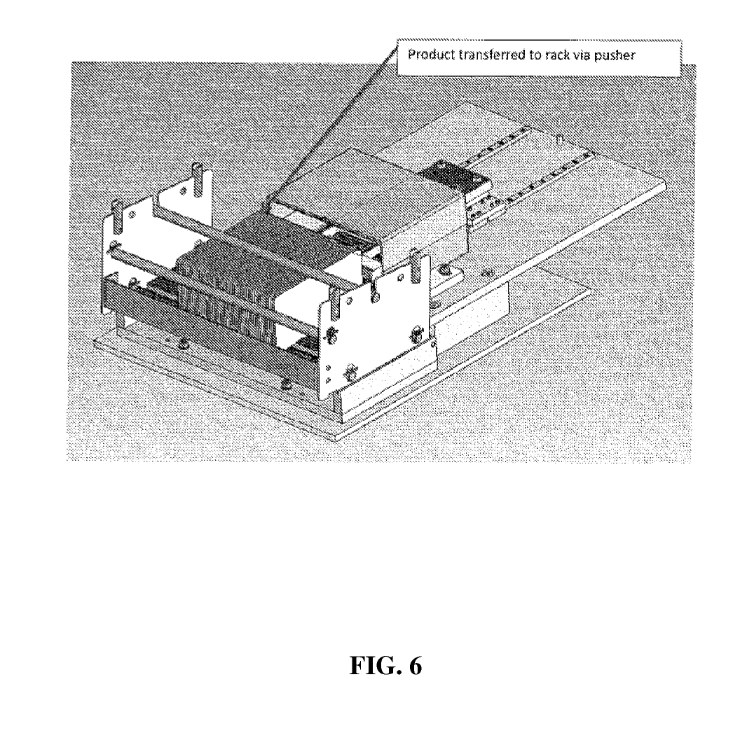

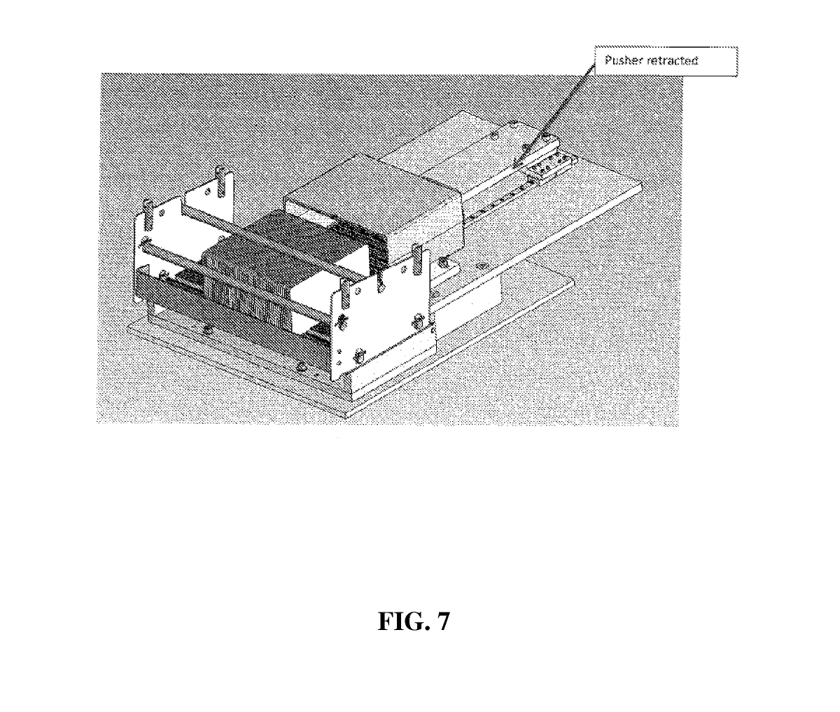

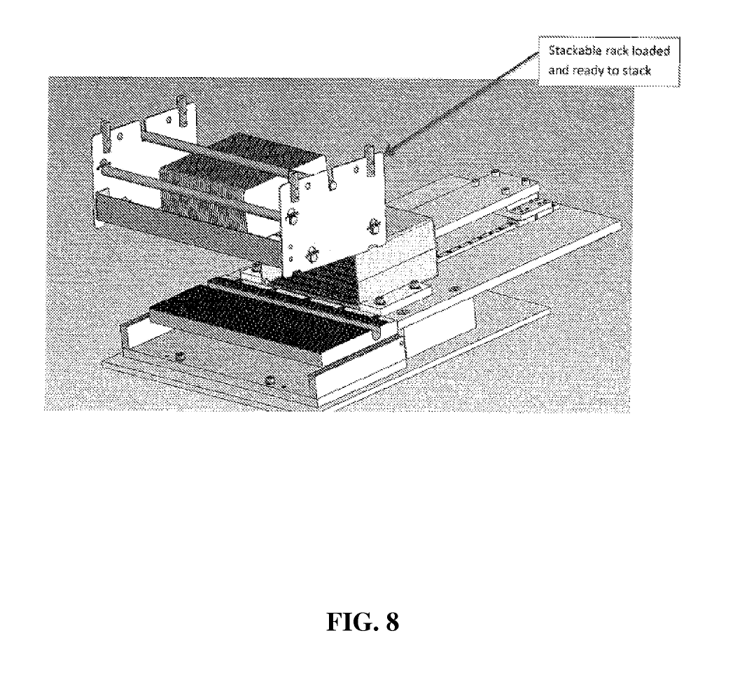

The “pusher” assembly is configured to pushingly engage the product through the transfer access aperture of the cartridge, which as noted above may involve pushing each of the plurality of individual separated and parallel instances of the product substantially simultaneously out of the cartridge onto the product-receiving member. Once pushed onto the transportable (and illustratively stackable) rack and the pusher is retracted, as shown in FIGS. 6-8, the product and rack may be transported from a first location (where the product was received) to a second location remote from the cartridge-receiving member. Note again that the transportable rack may be configured to stack with one or more other transportable racks at the second location, such as through various stacking mechanisms (e.g., tabs, slots, grooves, connectors, etc.).

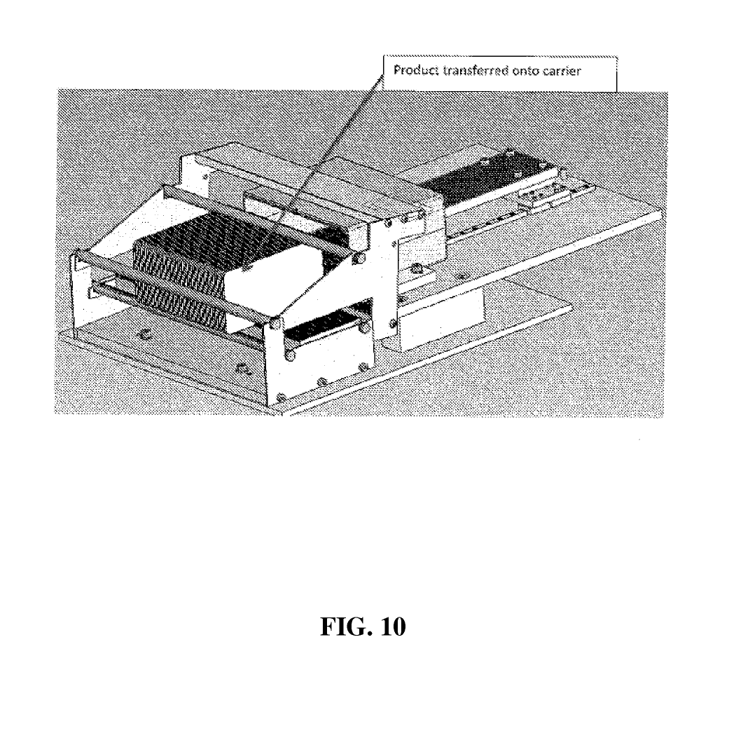

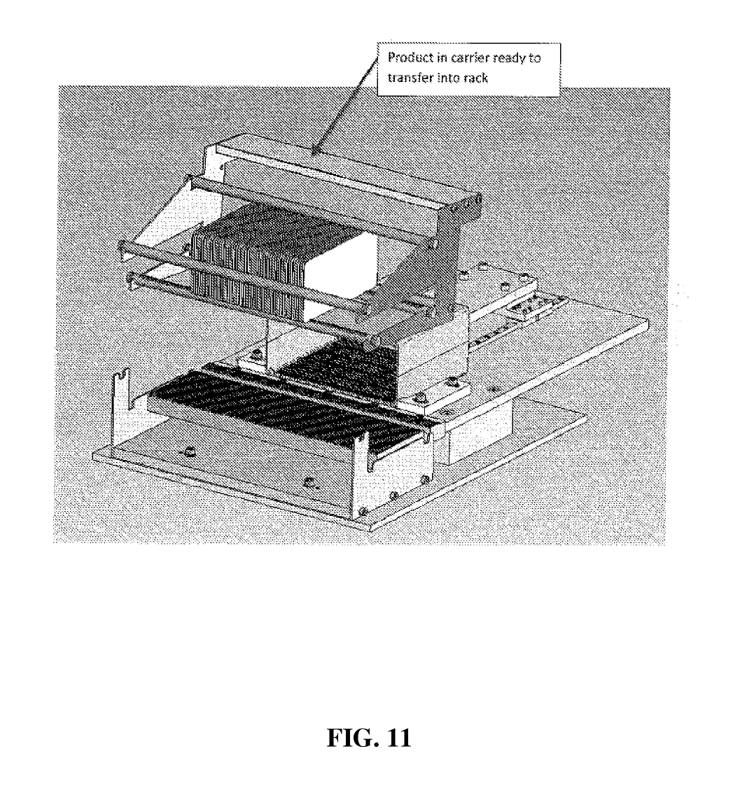

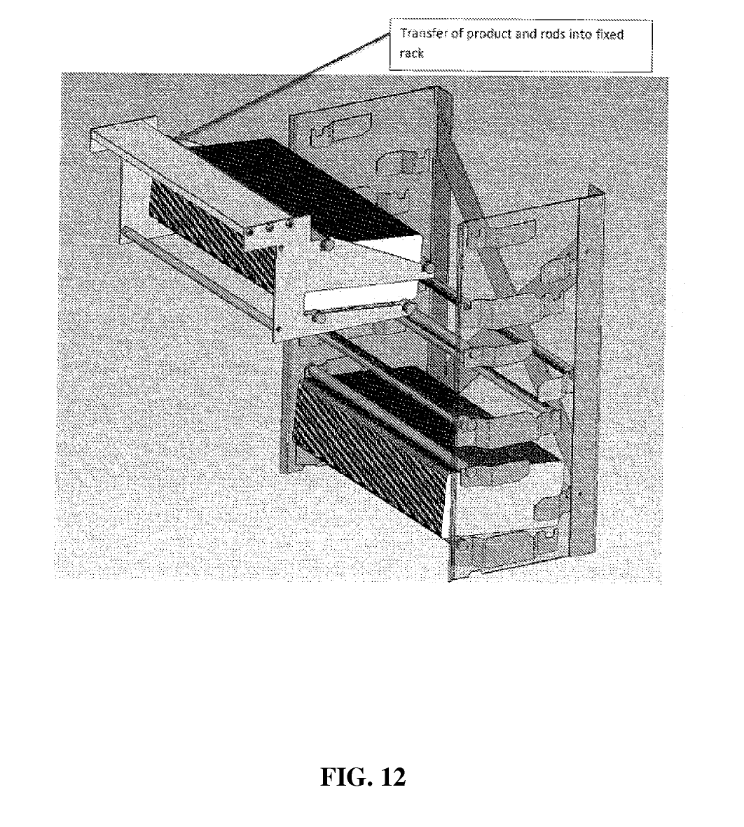

As an alternative transport embodiment, FIG. 9 illustrates an example product cartridge loaded to a transfer fixture and associated carrier (end effector). In particular, in this illustrative embodiment (with further reference generally to FIGS. 10-14), the bottom and rear supports are configured to be transported from a first location (where the product is received) to a second location remote from the cartridge-receiving member using a carrier to lift the bottom and rear supports and to transport them to a support rack at the second location, such as an annealing furnace in which the rack is positioned or is capable of being positioned. For instance, FIG. 10 illustrates an example of product being pushed from the product cartridge into the transfer fixture, and then FIG. 11 illustrates an example of product being moved by the carrier within the transfer fixture to the fixed rack in FIG. 12. Illustratively, the rack has first and second opposing walls with a plurality of brackets disposed thereon that are configured to receive and support the product-receiving member, that is, brackets to support at least the bottom support and rear support while carrying the product. Note that where the embodiment comprises a top support configured to compressively support the product against the bottom support (e.g., as shown), here the plurality of brackets would thus be configured to also receive and support the top support. Also, as mentioned above, where the supports are configured as rods, then the plurality of brackets may be configured to gravitationally receive the rods, accordingly (e.g., as shown).

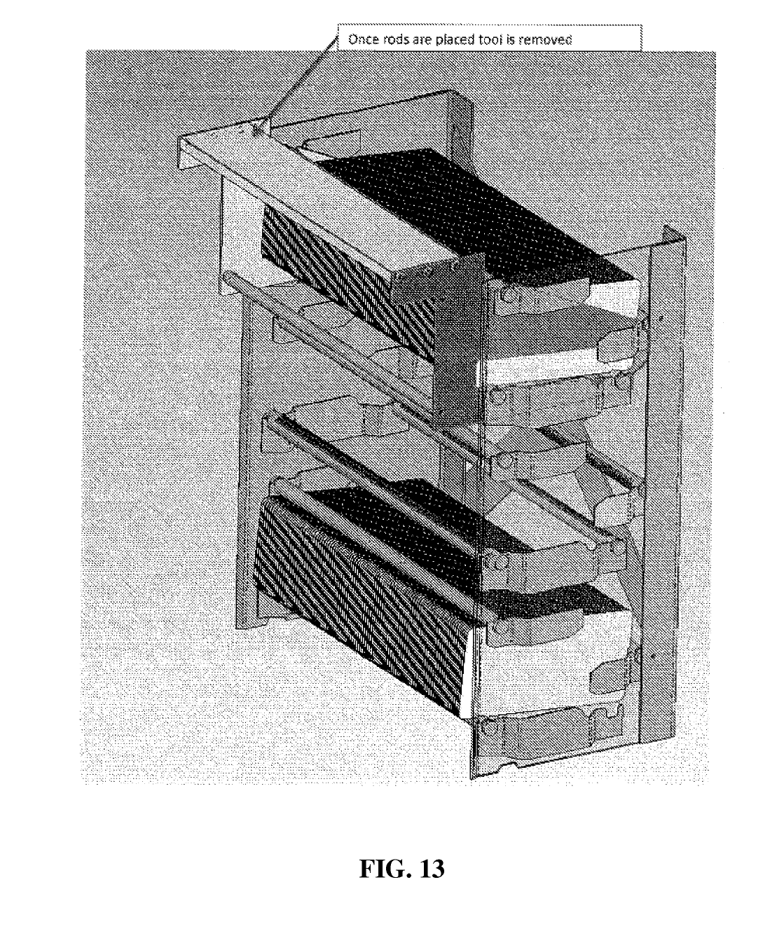

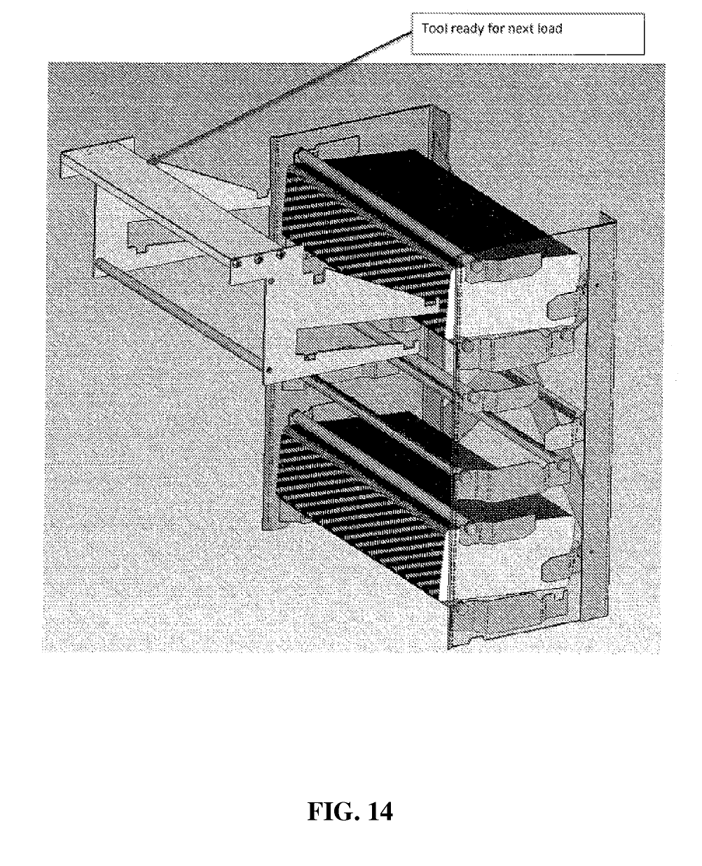

As shown in FIGS. 13-14, once the product is placed within the fixed rack, and the carrier/tool is removed (e.g., lowered to allow the rod supports to rest in the rack brackets), the carrier is ready to acquire new supports/rods, and transport further product.

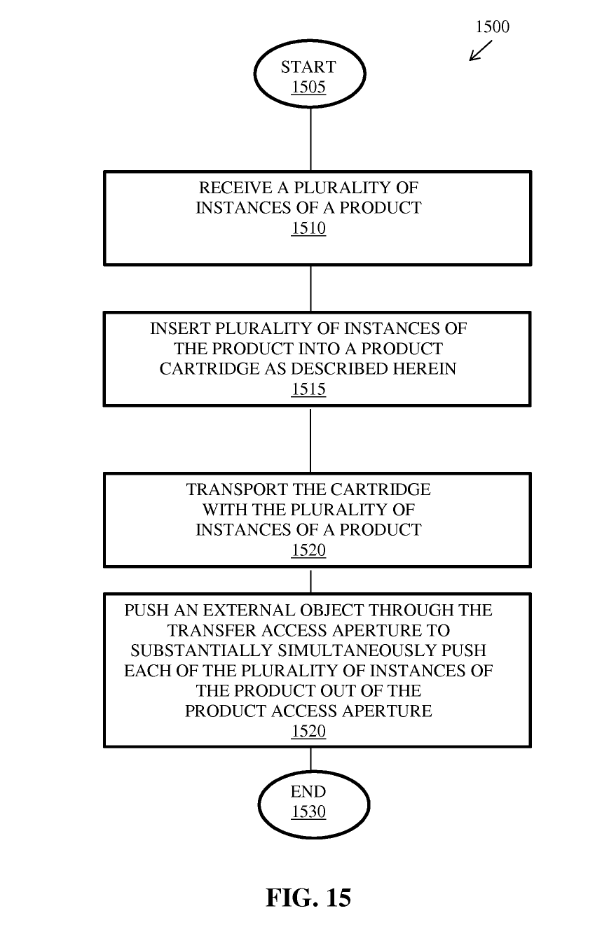

FIG. 15 illustrates an example simplified procedure 1500 for use with product cartridge described above with general reference to FIGS. 1-14. As shown in FIG. 15, the procedure 1500 may start at step 1505 and continues to step 1510, where, as described in greater detail above, a plurality of instances of a product may be received and then, in step 1515, may be inserted into a product cartridge as described in detail above. The cartridge with the plurality of instances of a product may then be transported in step 1520, where a cartridge-receiving mechanism can push an external object through the transfer access aperture to substantially simultaneously push each of the plurality of instances of the product out of the product access aperture in step 1525. The illustrative and simplified procedure 1500 may then end in step 1530.

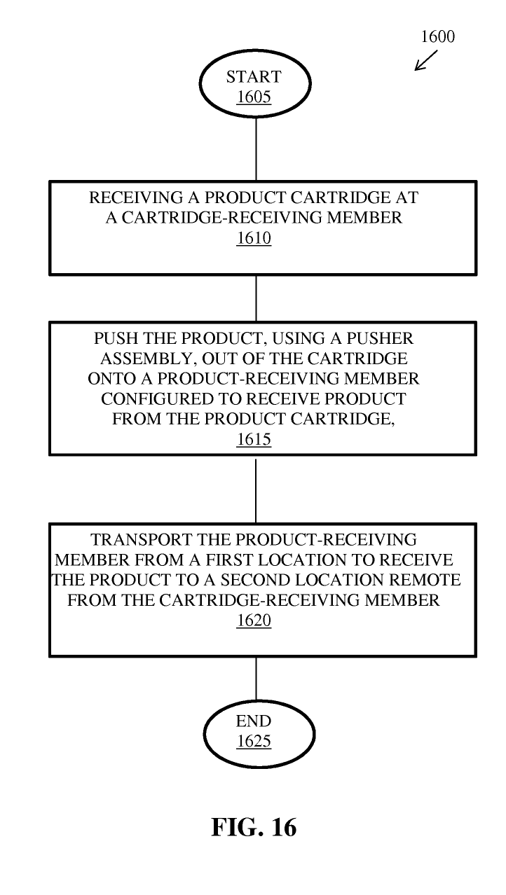

FIG. 16 illustrates an example simplified procedure 1600 for use with the transfer fixtures described above with general reference to FIGS. 1-14. As shown in FIG. 16, the procedure 1600 may start at step 1605, and continues to step 1610, where, as described in greater detail above, a cartridge-receiving member receives a product cartridge. As such, in step 1615, a pusher assembly pushes the product out of the cartridge onto a product-receiving member configured to receive product from the product cartridge, which as described above, has a bottom support to gravitationally support the product and a rear support to terminate receipt of the product and prevent egress of the product from the product-receiving member. Notably in one embodiment as mentioned above, the pusher assembly pushes each of a plurality of individual separated and parallel instances of the product substantially simultaneously out of the cartridge onto the product-receiving member, which may be held separated by a top support. Once removed from the cartridge, the product within the product-receiving member can be transported in step 1620 from a first location (where the product was received) to a second location remote from the cartridge-receiving member (where additional processing of the product may occur). As described above, the transport in step 1620 may be either as a transportable rack, e.g., stacking the transportable rack with one or more other transportable racks at the second location, or else may merely transport the bottom and rear supports (e.g., and top supports) from the first location to the second location using a carrier to lift the bottom and rear supports, and placing them in a fixed rack with receiving brackets. The illustrative and simplified procedure 1600 may then end in step 1625.

It should be understood that the steps shown in FIGS. 15-16 are merely examples for illustration, and certain steps may be included or excluded as desired. For example, the simplified procedure may also be performed with greater specificity, such as using various components described above but not specifically mentioned within the description of FIGS. 15-16, and may also be performed by different parties. Further, while a particular order of the steps is shown, this ordering is merely illustrative, and any suitable arrangement of the steps may be utilized without departing from the scope of the embodiments herein. Moreover, while the procedures are described separately, certain steps from each procedure may be incorporated into each other procedure, and the procedures are not meant to be mutually exclusive.

The components, arrangements, and techniques described herein, therefore, provide for mechanisms that may be advantageously used for the transport of products. In particular, the embodiments described herein provide high-density transfer of a product with minimal contact, and reduces the amount product handling. While there have been shown and described illustrative embodiments that provide for product transfer with an associated product cartridge, it is to be understood that various other adaptations and modifications may be made within the spirit and scope of the embodiments herein, with the attainment of some or all of their advantages. For example, while certain embodiments are described in terms of “gravitational”, “bottom,” and “rear”, other orientations may be used in accordance with the concepts herein, such that there is support on a “first edge” of the product (e.g., the bottom in the example above) and a stop on a “second edge” of the product that is perpendicular to the first edge (e.g., the rear in the example above). Therefore, it is the object of the appended claims to cover all such variations and modifications as come within the true spirit and scope of the embodiments herein.

What is claimed is:

1. An apparatus, comprising:
first and second opposing and substantially parallel and planar walls separated by a distance defined by a product to be transported by the apparatus, the first and second walls configured to define a product access aperture to allow ingress and egress of a plurality of instances of the product between the first and second walls;
product engaging members disposed on the first and second walls, the product engaging members configured to slidingly engage and secure the plurality of instances of the product in parallel when inserted into the product access aperture and at a defined spacing between the plurality of instances of the product; and
a transfer access aperture opposite the product access aperture and configured to allow an external object to substantially simultaneously push each of the plurality of instances of the product out of the product access aperture.

2. The apparatus as in claim 1, wherein the product engaging members comprise one of either a) individually spaced members along the first and second walls or b) singular members along the first and second walls defining channels into which instances of the product may slidingly engage.

3. The apparatus as in claim 1, wherein the product engaging members comprise one of either rollers or a slidingly engaging solid material.

4. The apparatus as in claim 3, wherein the slidingly engaging solid material is selected from a group consisting of: foam, felt, plastic, fire proof material, and heat resistant material.

5. The apparatus as in claim 1, wherein the transfer access aperture is sufficiently smaller than the distance between the first and second walls to prevent egress of the product through the transfer access aperture.

6. The apparatus as in claim 1, wherein the transfer access aperture is smaller than a span of the plurality of instances of the product, the apparatus further comprising:
a push plate configured to allow an external object to enter the transfer access aperture and push the push plate to substantially simultaneously push each of the plurality of instances of the product out of the product access aperture.

7. The apparatus as in claim 1, wherein the first and second walls are top and bottom walls of the apparatus, respectively.

8. The apparatus as in claim 1, wherein the defined spacing is a minimum distance defined by maximum deflection of two adjacent instances of the product to prevent contact between the two adjacent instances.

9. The apparatus as in claim 1, wherein pushing each of the plurality of instances of the product out of the product access aperture results in each of the plurality of instances of the product being completely removed from the apparatus.

10. The apparatus as in claim 1, further comprising:
an alignment mechanism to provide aligned engagement of the apparatus with a receiving member for one or both of ingress and egress of the product from the product access aperture.

11. The apparatus as in claim 1, further comprising:
a cover configured to prevent egress of inserted product from the product access aperture.

12. The apparatus as in claim 1, wherein the apparatus is generally rectangular in shape.

13. The apparatus as in claim 1, wherein the product comprises sapphire wafers.

14. The apparatus as in claim 1, wherein the first and second opposing walls are substantially parallel and planar.

15. A method, comprising:
receiving a plurality of instances of a product; and
inserting the plurality of instances of the product into a cartridge, the cartridge having: i) first and second opposing walls separated by a distance defined by the product, the first and second walls configured to define a product access aperture to allow ingress and egress of the plurality of instances of the product between the first and second walls; ii) product engaging members disposed on the first and second walls, the product engaging members configured to slidingly engage and secure the plurality of instances of the product in parallel when inserted into the product access aperture and at a defined spacing between the plurality of instances of the product; and iii) a transfer access aperture opposite the product access aperture and configured to allow an external object to substantially simultaneously push each of the plurality of instances of the product out of the product access aperture.

16. The method as in claim 15, further comprising:
transporting the cartridge with the plurality of instances of a product.

17. The method as in claim 16, further comprising:
pushing an external object through the transfer access aperture to substantially simultaneously push each of the plurality of instances of the product out of the product access aperture.

18. A method, comprising:
receiving a cartridge having a plurality of instances of a product, the cartridge having: i) first and second opposing walls separated by a distance defined by the product, the first and second walls configured to define a product access aperture to allow ingress and egress of the plurality of instances of the product between the first and second walls; ii) product engaging members disposed on the first and second walls, the product engaging members configured to slidingly engage and secure the plurality of instances of the product in parallel when inserted into the product access aperture and at a defined spacing between the plurality of instances of the product; and iii) a transfer access aperture opposite the product access aperture and configured to allow an external object to substantially simultaneously push each of the plurality of instances of the product out of the product access aperture; and
pushing an external object through the transfer access aperture to substantially simultaneously push each of the plurality of instances of the product out of the product access aperture.

19. A system, comprising:
a first mechanism to manage a plurality of instances of a product; and
a second mechanism to manage a cartridge having: i) first and second opposing walls separated by a distance defined by the product, the first and second walls configured to define a product access aperture to allow ingress and egress of the plurality of instances of the product between the first and second walls; ii) product engaging members disposed on the first and second walls, the product engaging members configured to slidingly engage and secure the plurality of instances of the product in parallel when inserted into the product access aperture and at a defined spacing between the plurality of instances of the product; and iii) a transfer access aperture opposite the product access aperture and configured to allow an external object to substantially simultaneously push each of the plurality of instances of the product out of the product access aperture.

20. The system as in claim 19, wherein the first mechanism to manage the plurality of instances of the product comprises insertion means to insert the plurality of instances of the product into the product access aperture.

21. The system as in claim 19, wherein the first mechanism to manage the plurality of instances of the product comprises removal means to push an external object through the transfer access aperture to substantially simultaneously push each of the plurality of instances of the product out of the product access aperture.

22. The system as in claim 19, wherein the first and second opposing walls are substantially parallel and planar.
